(19) United States
(12) Patent Application Publication
(10) Pub. No.: US 2023/0037158 A1
(43) Pub. Date: Feb. 2, 2023

(54) SEMICONDUCTOR MODULE

(71) Applicants: SUMITOMO ELECTRIC INDUSTRIES, LTD., Osaka (JP); BAYERISCHE MOTOREN WERKE AKTIENGESELLSCHAFT, Munchen (DE)

(72) Inventors: Christina LEGEN, Munchen (DE); Gerhard WOELFL, Munchen (DE); Hirotaka OOMORI, Osaka (JP); Masaki TANIYAMA, Osaka (JP); Satoshi HATSUKAWA, Osaka (JP); Takashi TSUNO, Osaka (JP)

(21) Appl. No.: 17/758,475

(22) PCT Filed: Jan. 16, 2020
(86) PCT No.: PCT/JP2020/001306

§ 371 Date: Jul. 7, 2022

(51) Int. Cl. H01L 23/047; H01L 23/373; H01L 25/07

(52) U.S. Cl. CPC H01L 23/047; H01L 23/3735; H01L 25/072

(57) ABSTRACT

A semiconductor module includes a base member; a circuit board provided on the base member and including a positive electrode pad, a negative electrode pad, and semiconductor devices; a housing formed in a frame shape and attached to the base member; a first electrode plate electrically coupled to the positive electrode pad and having a first flat plate portion; a second electrode plate electrically coupled to the negative electrode pad and having a second flat plate portion; and a first insulating member. The first flat plate portion and the second flat plate portion are disposed in parallel from the inside to outside of the housing. The first flat plate portion has a first external connection terminal situated outside the housing, and the second flat plate portion has a second external connection terminal situated outside the housing. The first insulating member is sandwiched between the first and the second external connection terminals.

### TECHNICAL FIELD

The disclosures herein relate to a semiconductor module.

### BACKGROUND ART

In semiconductor modules, a pair of semiconductor devices is connected in series to a power supply, and an output is obtained from between the pair of semiconductor devices. Semiconductor modules that include semiconductor devices capable of producing a large electric current are used in electric vehicles and other electric power applications. It is known that in such semiconductor devices, surge voltage is generated between a positive-side input terminal and a negative-side input terminal of a power conversion circuit when transistors, which are semiconductor devices, are turned on or off.

### CITATION LIST

### Patent Literature

[PTL 1] Japanese Laid-open Patent Publication No. 2015-35627

### SUMMARY OF INVENTION

According to an embodiment of the present disclosure, a semiconductor module includes a base member;

a circuit board provided on the base member and including a positive electrode pad, a negative electrode pad, and semiconductor devices, the semiconductor devices being electrically coupled to the positive electrode pad and the negative electrode pad; a housing formed in a frame shape and attached to the base member so as to surround the positive electrode pad and the negative electrode pad; a first electrode plate electrically coupled to the positive electrode pad and having a first flat plate portion; a second electrode plate electrically coupled to the negative electrode pad and having a second flat plate portion; and a first insulating member. The first flat plate portion of the first electrode plate and the second flat plate portion of the second electrode plate are disposed in parallel from the inside to the outside of the housing. The first flat plate portion of the first electrode plate has a first external connection terminal situated outside the housing, and the second flat plate portion of the second electrode plate has a second external connection terminal situated outside the housing, the first insulating member being sandwiched between the first external connection terminal and the second external connection terminal.

### BRIEF DESCRIPTION OF DRAWINGS

FIG. 1 is a perspective view of a base member according to an embodiment of the present invention;

FIG. 2 is a diagram illustrating components of a semiconductor module according to the embodiment of the present invention;

FIG. 3 is a perspective view of the semiconductor module according to the embodiment of the present invention;

FIG. 4 is a cross-sectional view of the semiconductor module according to the embodiment of the present invention;

FIG. 5 is an equivalent circuit diagram of a main portion of the semiconductor module according to the embodiment of the present invention;

FIG. 6 is a perspective view of a housing according to the embodiment of the present invention;

FIG. 7 is a perspective view of a P-electrode plate according to the embodiment of the present invention;

FIG. 8 is a side view of the P-electrode plate according to the embodiment of the present invention;

FIG. 9 is a perspective view of an N-electrode plate according to the embodiment of the present invention;

FIG. 10 is a side view of the N-electrode plate according to the embodiment of the present invention;

FIG. 11 is a perspective view of an O-electrode plate according to the embodiment of the present invention;

FIG. 12 is a side view of the O-electrode plate according to the embodiment of the present invention;

FIG. 13 is a perspective view of a lid according to the embodiment of the present invention;

FIG. 14 is a perspective view of insulating paper according to the embodiment of the present invention;

FIG. 15 is a diagram (1) illustrating an internal structure of the semiconductor module according to the embodiment of the present invention;

FIG. 16 is a diagram (2) illustrating the internal structure of the semiconductor module according to the embodiment of the present invention;

FIG. 17 is a diagram (3) illustrating the internal structure of the semiconductor module according to the embodiment of the present invention;

FIG. 18 is a diagram (1) illustrating a creepage insulating portion of a housing of the semiconductor module according to the embodiment of the present invention;

FIG. 19 is a diagram (2) illustrating the creepage insulating portion of the housing of the semiconductor module according to the embodiment of the present invention;

FIG. 20 is a diagram (3) illustrating the creepage insulating portion of the housing of the semiconductor module according to the embodiment of the present invention;

FIG. 21 is a diagram (4) illustrating the creepage insulating portion of the housing of the semiconductor module according to the embodiment of the present invention;

FIG. 22 is a diagram (5) illustrating the creepage insulating portion of the housing of the semiconductor module according to the embodiment of the present invention;

FIG. 23 is a perspective view (1) of the semiconductor module to which a P-busbar and an N-busbar are connected according to the embodiment of the present invention;

FIG. 24 is a perspective view (2) of the semiconductor module to which the P-busbar and the N-busbar are connected according to the embodiment of the present invention;

FIG. 25 is a side view of the semiconductor module to which the P-busbar and the N-busbar are connected according to the embodiment of the present invention; and

FIG. 26 is a cross-sectional view of the semiconductor module to which the P-busbar and the N-busbar are connected according to the embodiment of the present invention.

### DESCRIPTION OF EMBODIMENTS

First, embodiments of the present disclosures will be listed and described. In the following, the same or corresponding elements are denoted by the same reference numerals and a duplicate description thereof will be omitted.

A semiconductor module according to an embodiment of the present invention a base member; a circuit board provided on the base member and including a positive electrode pad, a negative electrode pad, and semiconductor devices, the semiconductor devices being electrically coupled to the positive electrode pad and the negative electrode pad; a housing formed in a frame shape and attached to the base member so as to surround the positive electrode pad and the negative electrode pad; a first electrode plate electrically coupled to the positive electrode pad and having a first flat plate portion; a second electrode plate electrically coupled to the negative electrode pad and having a second flat plate portion; and a first insulating member. The first flat plate portion of the first electrode plate and the second flat plate portion of the second electrode plate are disposed in parallel from the inside to the outside of the housing. The first flat plate portion of the first electrode plate has a first external connection terminal situated outside the housing, and the second flat plate portion of the second electrode plate has a second external connection terminal situated outside the housing, the first insulating member being sandwiched between the first external connection terminal and the second external connection terminal.

In semiconductor modules, it is known that, surge voltage is generated between a positive-side input terminal and a negative-side input terminal of a power conversion circuit when transistors, which serve as semiconductor devices are turned on or off. In such semiconductor modules, it is desired to reduce surge voltage. The inventors have conceived the idea of generating mutual inductance between a first electrode plate, which serves as a positive electrode, and a second electrode plate, which serves as a negative electrode, by disposing the first electrode plate and the second electrode plate in parallel. By generating mutual inductance in the above manner, it becomes possible to reduce the inductance of the semiconductor module, thus allowing surge voltage to be reduced.

The first insulating member is insulating paper.

The semiconductor module further includes a second insulating member that is situated outside the housing so as to surround, in a plan view, the first external connection terminal of the first electrode plate and the second external connection terminal of the second electrode plate.

The second insulating member is a part of the housing.

The first external connection terminal of the first electrode plate has a first through-hole, the second external connection terminal of the second electrode plate has a second through-hole, and in a plan view, a position of the first through-hole of the first external connection terminal coincides with a position of the second through-hole of the second external connection terminal.

The semiconductor devices are formed of a material including SiC.

### Details of Embodiments

In the following, embodiments of the present invention will be described in detail; however, the present invention is not limited to the embodiments described below. In the embodiments, an X1-X2 direction, a Y1-Y2 direction, and a Z1-Z2 direction are defined as directions orthogonal to each other. A plane including the X1-X2 direction and the Y1-Y2 direction is described as an XY-plane, a plane including the Y1-Y2 direction and the Z1-Z2 direction is described as a YZ-plane, and a plane including Z1-Z2 direction and the X1-X2 direction is described as a ZX-plane.

First, semiconductor modules including semiconductor devices capable of producing a large electric current will be described. In the semiconductor modules, serving as power modules, semiconductor devices formed of Si (silicon) have been used as switching elements capable of producing a large electric current. However, there has been a demand for improvement in properties.

Semiconductor devices formed of SiC (silicon carbide) are capable of a high-speed on/off operation because the switching speed is high. In the semiconductor devices formed of SiC, a current can be quickly decreased at the time of switch-off, such that switching loss can be reduced.

However, the high-speed switching of the semiconductor devices formed of SiC would cause a new problem that surge voltage would increase at the time of switching. A value of surge voltage V is calculated by V=L·t, where i denotes a current and L denotes inductance. A value of di/dt depends on the switching speed of transistors, which serve as semiconductor devices, and as the switching speed increases, the value of di/dt increases. Because the semiconductor devices formed of SiC enable the high-speed switching as compared to semiconductor devices formed of Si, the value of di/dt becomes larger, and as a result, the surge voltage V increases. If the surge voltage V becomes or exceeds a breakdown voltage of the semiconductor device, the semiconductor devices may be broken, which is not preferable.

An object of the present disclosures is to reduce surge voltage without decreasing the switching speed of semiconductor devices in a semiconductor module.

Specifically, the surge voltage V can be calculated by V=L·di/dt, as described above. In order to maintain the high-speed switching, di/dt cannot be decreased. Thus, the surge voltage V is decreased by decreasing the inductance L.

### First Embodiment

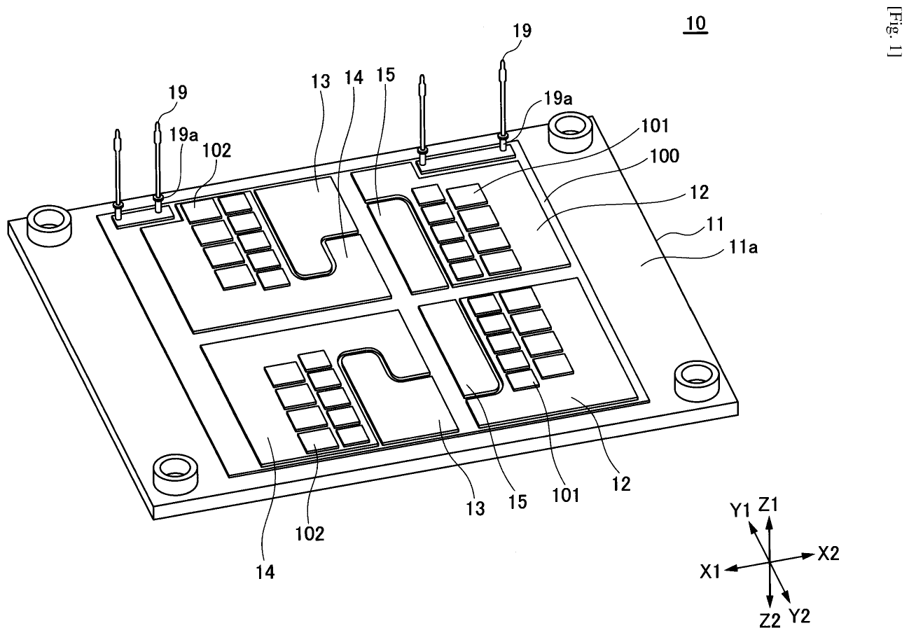

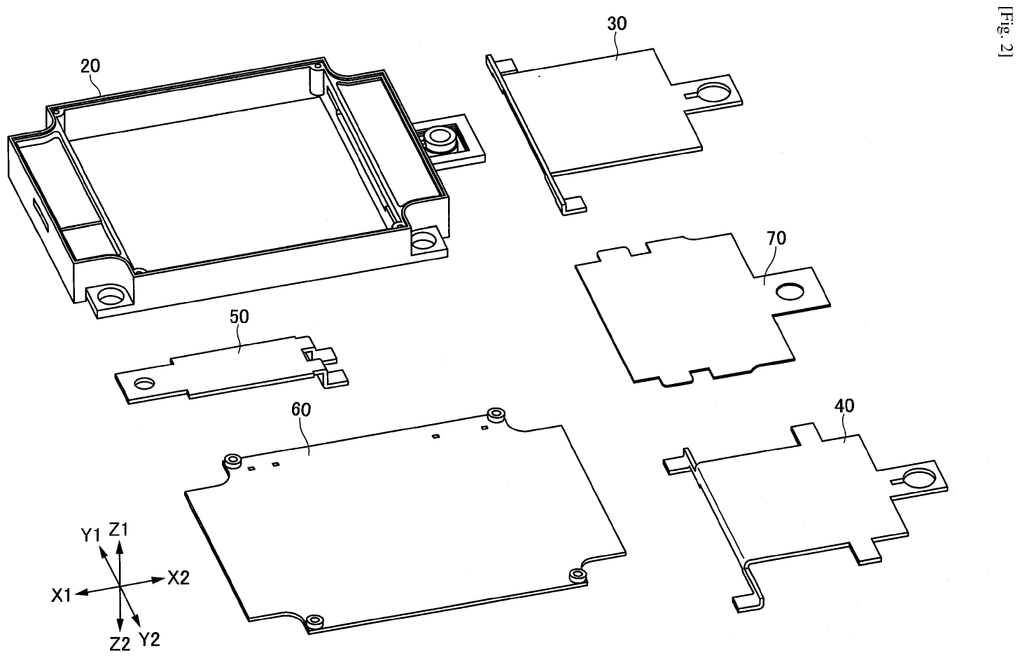

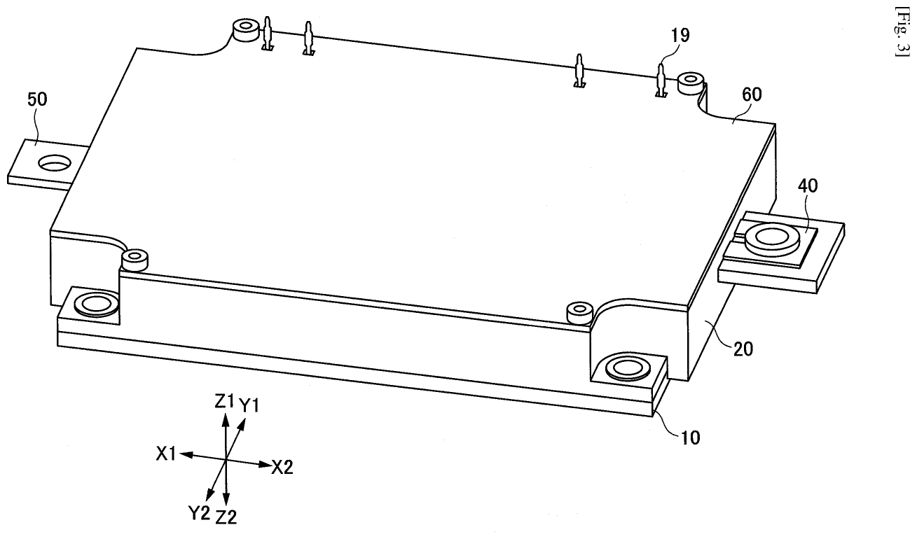

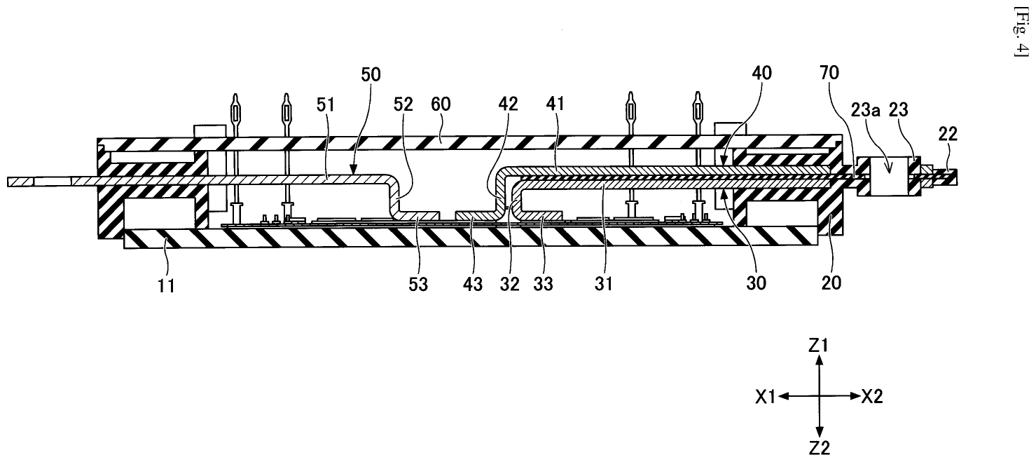

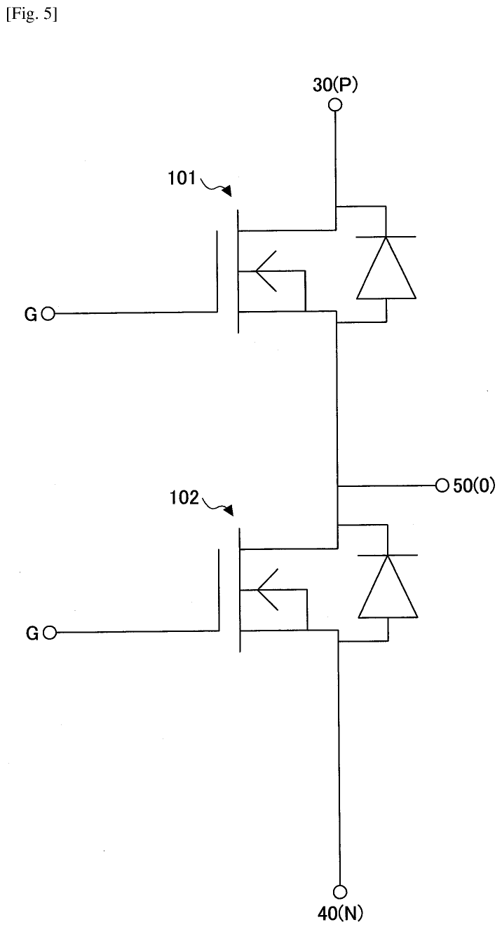

A semiconductor module according to a first embodiment will be described. The semiconductor module according to the first embodiment includes a base member 10 illustrated in FIG. 1, a housing 20 illustrated in FIG. 2, a P-electrode plate 30, an N-electrode plate 40, an O-electrode plate 50, a lid 60, and an insulating paper 70. The semiconductor module according to the present embodiment is configured by the above components. FIG. 3 is a perspective view of the semiconductor module according to the present embodiment. FIG. 4 is a cross-sectional view of an internal structure of the semiconductor module, and FIG. 5 is an equivalent circuit diagram of a main portion of the semiconductor module.

The semiconductor module according to the present embodiment may be used for an inverter circuit constituting a driving circuit for driving an electric motor. The electric motor is used, for example, as a power source for an electric vehicle (including a hybrid vehicle), a train, or an industrial robot. The semiconductor module may also be used for an inverter circuit that converts electric power generated by solar cells, wind turbines, and other generators (particularly private electric power generators) so as to be consistent with electric power of a commercial power supply.

As illustrated in FIG. 1, the base member 10 includes a base plate 11 and a circuit board 100. The base plate 11 is formed of metal such as copper, and is formed in a rectangular shape. The circuit board 100 is disposed on the surface 11a of the base plate 11. The circuit board 100 includes an insulating ceramic substrate, and copper foils formed on both sides of the ceramic substrate. P-electrode pads 12, O-electrode pads 15, N-electrode pads 13, and O-electrode pads 14 are formed on the surface of the circuit board 100. A plurality of first transistors 101 are attached and electrically connected to each of the P-electrode pads 12, and a plurality of second transistors 102 are attached and electrically connected to each of the O-electrode pads 14.

The O-electrode pad 15 and the O-electrode pad 14 of the circuit board 100 are connected by wire bonding (not illustrated) and are electrically conductive.

The first transistors 101 and the second transistors 102 are vertical transistors formed of SiC, and may have a chip size of 6 mm per-side square. In the present embodiment, the first transistors 101 and the second transistors 102 are metal-oxide-semiconductor field-effect transistors (MOSFETs) having the same structure. The first transistors 101 and the second transistors 102 may be insulated-gate bipolar transistors (IGBTs). The first transistors 101 and the second transistors 102 may be formed of Si or wide-bandgap semiconductors such as GaN, and are preferably formed of SiC.

Drain electrodes on the lower surfaces of the first transistors 101 are placed on the P-electrode pads 12, and are electrically connected to the P-electrode pads 12 through solder or sintered material. Gate electrodes on the upper surfaces of the first transistors 101 are electrically connected to control wires of the first transistors 101 by wire bonding. Source electrodes are electrically connected to the O-electrode pads 15 by wire bonding.

Drain electrodes on the lower surfaces of the second transistors 102 are placed on the O-electrode pads 14, and are electrically connected to the O-electrode pads 14 through solder or sintered material. Gate electrodes on the upper surfaces of the second transistors 102 are electrically connected to control wires of the second transistors 102 by wire bonding. Source electrodes are electrically connected to the N-electrode pads 13 by wire bonding. Note that wire bonding and bonding pads are not illustrated for convenience in the drawings.

Further, the base member 10 includes a plurality of press-fit pins 19 for electrically connecting wires of the circuit board 100 to the outside. The press-fit pins 19 are placed into press-fit pin holders 19a bonded to the wires of the circuit board 100 through solder, and are each electrically connected to a corresponding wire.

In the semiconductor module according to the present embodiment, as will be described below, the P-electrode plate 30 is connected to the P-electrode pads 12, the N-electrode plate 40 is connected to the N-electrode pads 13, and the O-electrode plate 50 is connected to the O-electrode pads 14. Positive voltage is applied to the P-electrode plate 30, and negative voltage is applied to the N-electrode plate 40. By alternately applying predetermined gate voltages to the gates of the first transistors 101 and the gates of the second transistors 102, an output is obtained from the O-electrode plate 50. As illustrated in FIG. 4, a flat plate portion 31 that is parallel to the XY-plane of the P-electrode plate 30 and a flat plate portion 41 that is parallel to the XY-plane of the N-electrode plate 40 are disposed in parallel. Further, the flat plate portion 31 of the P-electrode plate 30 and the flat plate portion 41 of the N-electrode plate 40 continue to be parallel from the inside to the outside of the housing 20 on the X2 side. In the present disclosure, an area surrounded by the frame of the housing 20 may be described as the inside of the housing 20, and the outside of the frame of the housing 20 may be described as the outside of the housing 20. Further, in the present disclosure, the term “parallel” is not intended to be construed in a strict sense, and is intended to be construed in a wider sense within the scope of the present invention.

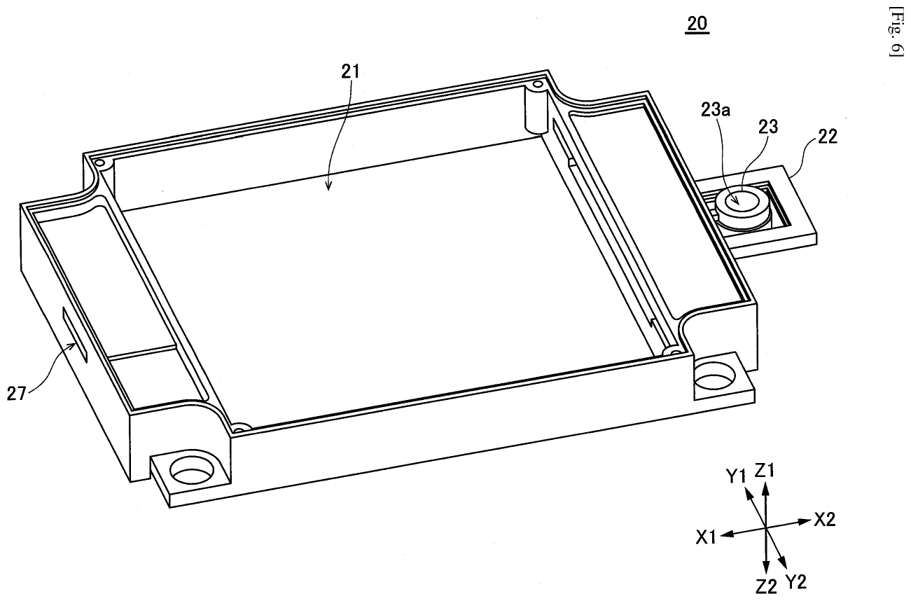

As illustrated in FIG. 6, the housing 20 is formed of an insulating resin material, and is formed in a frame shape. An opening 21 through the Z1-Z2 direction is formed at the center of the housing 20, and the Y1-Y2 sides and the X1-X2 sides of the housing 20 are closed. A creepage insulating portion 22 protruding outwardly from the housing 20 and a cylindrical portion 23 are provided on the X2 side of the housing 20. The cylindrical portion 23 has a screw hole 23a through the cylindrical portion 23 in the Z1-Z2 direction.

Because the housing 20 is formed of an insulating resin material, the creepage insulating portion 22 and the cylindrical portion 23 are also formed of the insulating material. The creepage insulating portion 22 is provided around the cylindrical portion 23, and there is a space between the creepage insulating portion 22 and the cylindrical portion 23. In addition, a connection hole 27 connecting the inside and the outside of the housing 20 is provided on the Z1 side of the housing 20. The O-electrode plate 50 is inserted into the connection hole 27.

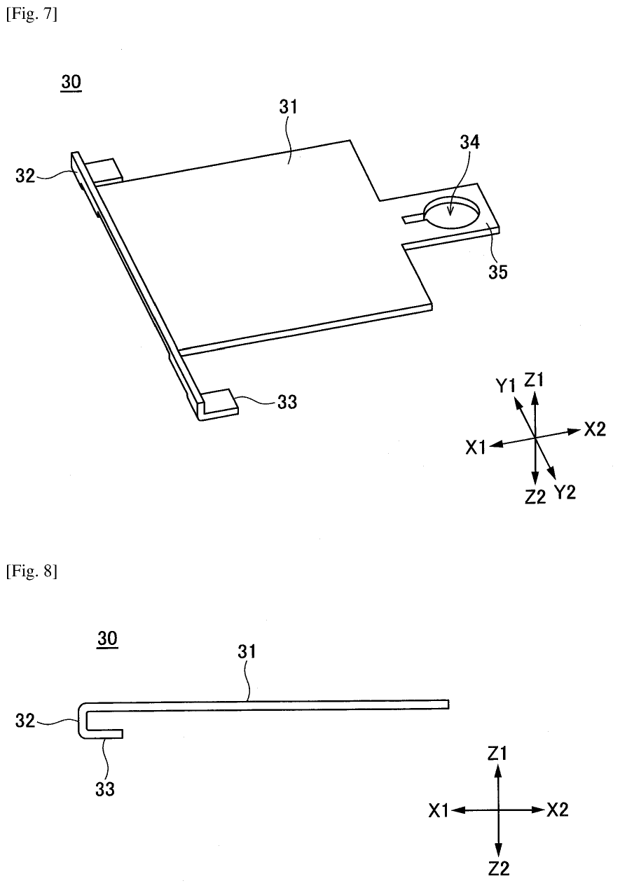

As illustrated in FIG. 7 and FIG. 8, the P-electrode plate 30 is formed by processing a metal plate such as copper having a thickness of approximately 1 mm. FIG. 7 is a perspective view of the P-electrode plate 30. FIG. 8 is a side view of the P-electrode plate 30. The P-electrode plate 30 has the flat plate portion 31 parallel to the XY plane. The end portion of the X1 side of the P-electrode plate 30 is bent twice at approximately right angles along the Y1-Y2 direction, so as to form a vertical portion 32 and connection portions 33. The connection portions 33 are connected to the P-electrode pads 12, are bent in a direction parallel to the XY plane, and are approximately parallel to the flat plate portion 31. The vertical portion 32 connects the flat plate portion 31 and the connection portions 33, and is bent in a direction parallel to the YZ plane. The connection portions 33, which serve as electrode terminals, may each have a size of 3 mm per-side square or 4 mm per-side square. In the P-electrode plate 30, the connection portions 33 are bent at right angles to the vertical portion 32 in the X2 direction. An external connection terminal 35 having a through-hole 34 is provided at the end portion of the X2 side of the flat plate portion 31. The through-hole 34 passes through the flat plate portion 31 in the Z1-Z2 direction.

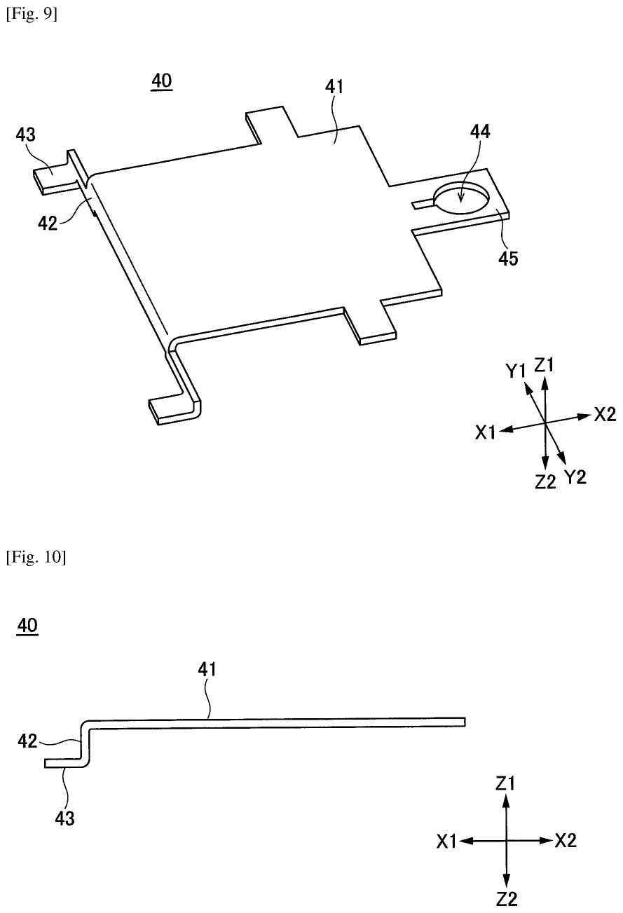

As illustrated in FIG. 9 and FIG. 10, the N-electrode plate 40 is formed by processing a metal plate such as copper having a thickness of approximately 1 mm. FIG. 9 is a perspective view of the N-electrode plate 40. FIG. 10 is a side view of the N-electrode plate 40. The N-electrode plate 40 has the flat plate portion 41 parallel to the XY plane. The end portion of the X1 side of the P-electrode plate 30 is bent twice at approximately right angles along the Y1-Y2 direction, so as to form a vertical portion 42 and connection portions 43. The connection portions 43 are connected to the N-electrode pads 13, are bent in a direction parallel to the XY plane, and are approximately parallel to the flat plate portion 41. The vertical portion 42 connects the flat plate portion 41 and the connection portions 43, and is bent in a direction parallel to the YZ plane. The connection portions 43, which serve as electrode terminals, may each have a size of 3 mm per-side square or 4 mm per-side square. In the N-electrode plate 40, the connection portions 43 are bent at right angles to the vertical portion 42 in the X1 direction. An external connection terminal 45 having a through-hole 44 is provided at the end portion of the X2 side of the flat plate portion 31. The through-hole 44 passes through the flat plate portion 41 in the Z1-Z2 direction.

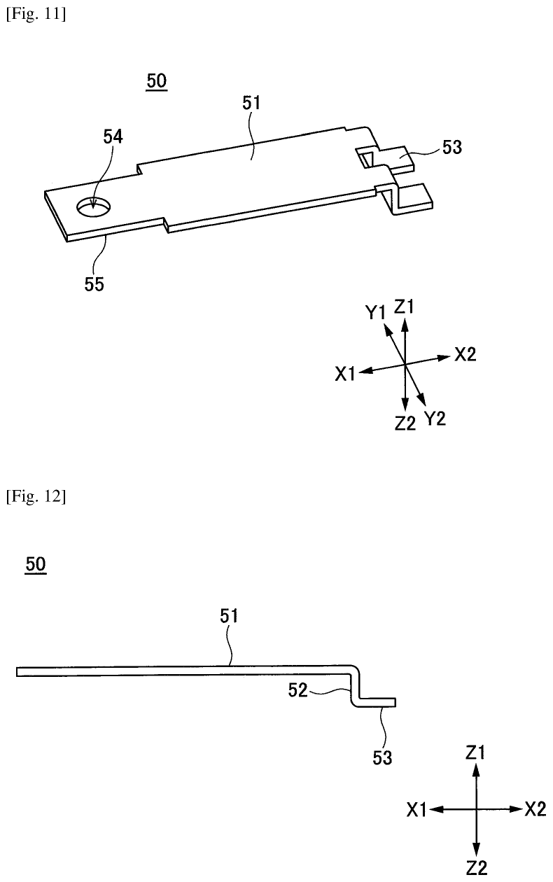

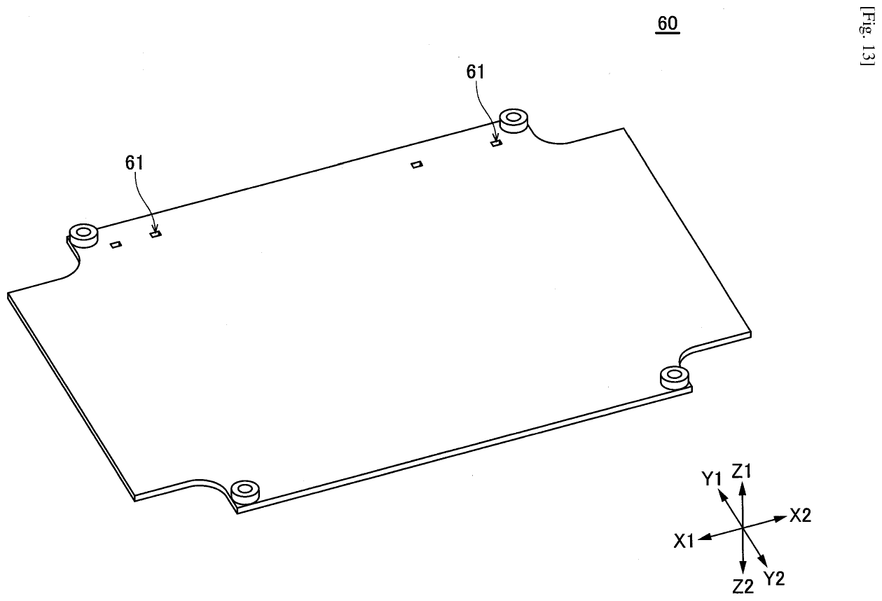

As illustrated in FIG. 11 and FIG. 12, the O-electrode plate 50 is formed by processing a metal plate such as copper having a thickness of approximately 1 mm, with the longer side being in the X1-X2 direction. FIG. 11 is a perspective view of the O-electrode plate 50. FIG. 12 is a side view of the O-electrode plate 50. The O-electrode plate 50 has a flat plate portion 51 parallel to the XY plane. The end portion of the X2 side of the O-electrode plate 50 is bent twice at approximately right angles along the Y1-Y2 direction, so as to form a vertical portion 52 and connection portions 53. The connection portions 53 are connected to O-electrode pads 14, are bent in a direction parallel to the XY plane, and are approximately parallel to the flat plate portion 51. The vertical portion 52 connects the flat plate portion 51 and the connection portions 53, and is bent in a direction parallel to the YZ plane. An external connection terminal 55 having a through-hole 54 is provided at the end portion of the X1 side of the flat plate portion 51. The through-hole 54 passes through the flat plate portion 51 in the Z1-Z2 direction. The connection portions 53, which serve as electrode terminals, may each have a size of 3 mm per-side square or 4 mm per-side square. In the O-electrode plate 50, the connection portions 53 are bent at right angles to the vertical portion 52 in the X2 direction.

As illustrated in FIG. 13, the lid 60 is a flat plate and has a plurality of through-holes 61 through which the press-fit pins 19 provided on the base member 10 are inserted.

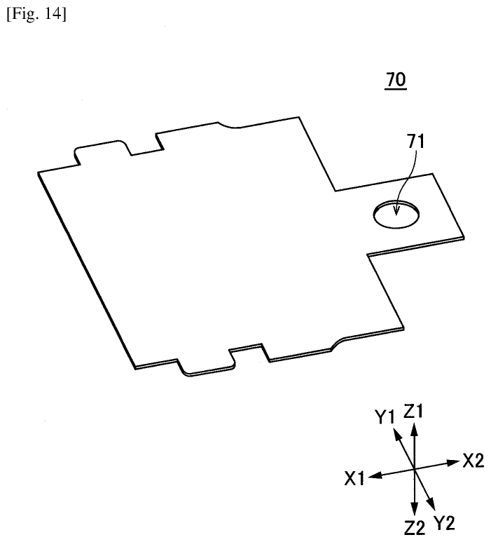

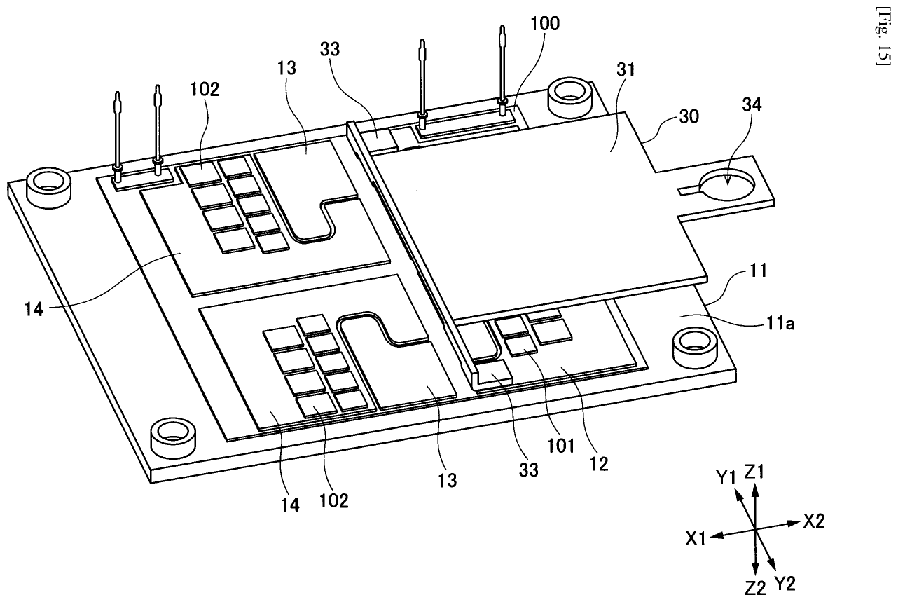

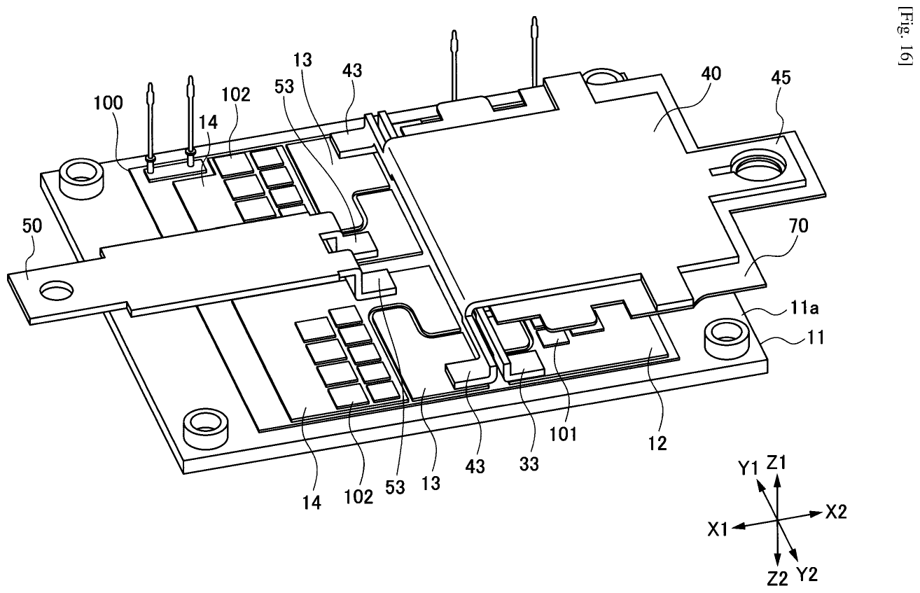

As illustrated in FIG. 14, the insulating paper 70 is paper serving as an insulator, and is placed between the flat plate portion 31 of the P-electrode plate 30 and the flat plate portion 41 of the N-electrode plate 40. Therefore, the insulating paper 70 has approximately the same size as or a slightly larger size than the flat plate portion 31 of the P-electrode plate 30 and the flat plate portion 41 of the N-electrode plate 40. The insulating paper 70 has a through-hole 71 that passes through the insulating paper 70 in the Z1-Z2 direction. By providing the insulating paper 70 between the flat plate portion 31 of the P-electrode plate 30 and the flat plate portion 41 of the N-electrode plate 40, it becomes possible to securely ensure insulation between the flat plate portion 31 of the P-electrode plate 30 and the flat plate portion 41 of the N-electrode plate 40. In addition, the breakdown voltage between the flat plate portion 31 of the P-electrode plate 30 and the flat plate portion 41 of the N-electrode plate 40 can be increased, thus allowing the distance between the flat plate portion 31 of the P-electrode plate 30 and the flat plate portion 41 of the N-electrode plate 40 to be narrowed. In the present application, the insulating paper 70 may be referred to as a first insulating member. Further, the creepage insulating portion 22 of the housing 20 may be referred to as a second insulating member.

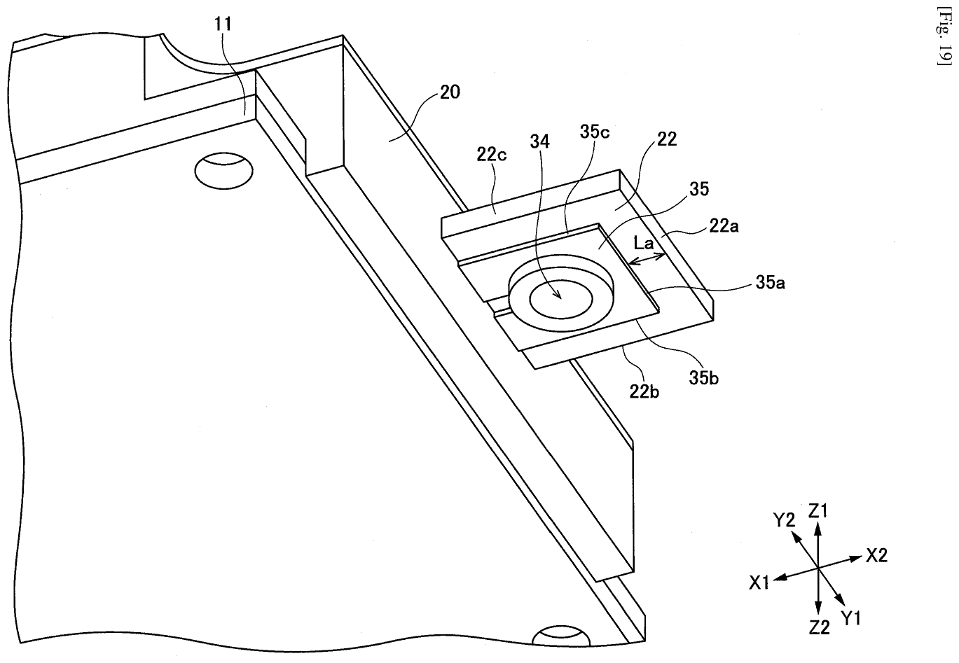

The housing 20 illustrated in FIG. 17 is filled with an insulating resin material (not illustrated), and after the insulating resin material is cured, the Z1 side of the housing 20 is covered by the lid 60.

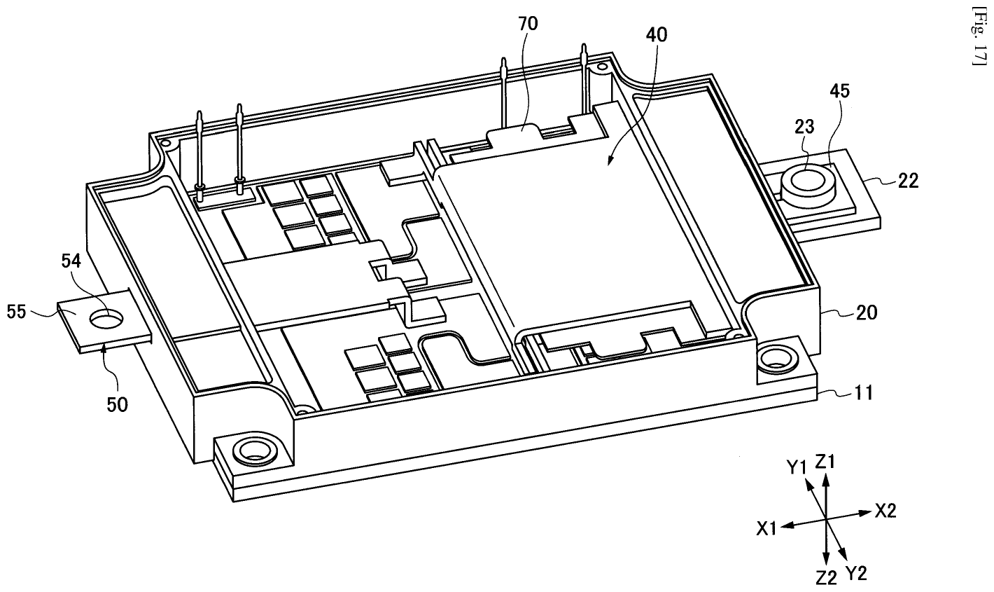

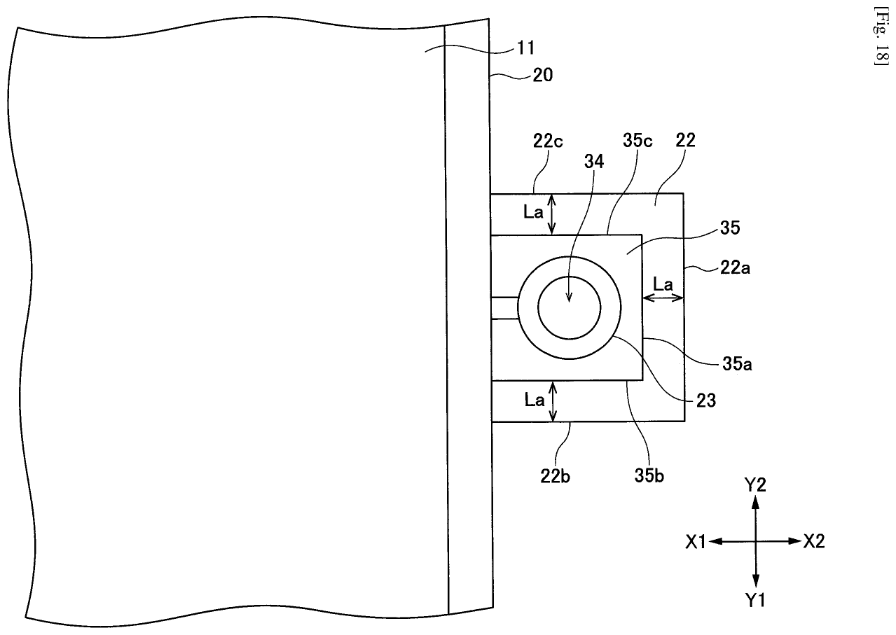

Next, the P-electrode plate 30, the N-electrode plate 40, and the O-electrode plate 50 attached to the housing 20 and to the circuit board 100 of the semiconductor module according to the present embodiment will be described. FIG. 15 is a diagram illustrating a state in which the P-electrode plate 30 is attached to the circuit board 100. FIG. 16 is a diagram illustrating a state in which the N-electrode plate 40 is attached to the circuit board 100, and further, the O-electrode plate 50 is attached to the circuit board 100. FIG. 17 is a diagram illustrating a state in which the housing 20 is attached.

As illustrated in FIG. 15, the connection portions 33 of the P-electrode plate 30 are welded to the P-electrode pads 12 of the circuit board 100 by ultrasonic welding. Further, as illustrated in FIG. 16, the connection portions 43 of the N-electrode plate 40 are welded to the N-electrode pads 13 of the circuit board 100 by ultrasonic welding, and the connection portions 53 of the O-electrode plate 50 are welded to the O-electrode pads 14 by ultrasonic welding. The N-electrode plate 40 is welded after the insulating paper 70 is placed on the surface of the Z1 side of the flat plate portion 31 of the P-electrode plate 30, which has been already welded.

As illustrated in FIG. 17, the housing 20 is bonded to the surface 11a of the base plate 11 by an adhesive. The base member 10 is disposed parallel to the XY-plane, with the longer side being in the X1-X2 direction and the shorter side being in the Y1-Y2 direction. The housing 20 is bonded to the surface of the Z1 side, which is the surface 11a, of the base plate 11. The housing 20 is bonded to the surface 11a of the base plate 11 such that the circuit board 100 is placed within the opening 21 of the housing 20.

In this state, the external connection terminal 35 of the P-electrode plate 30 having the through-hole 34, the external connection terminal 45 of the N-electrode plate 40 having the through-hole 44, and the portion of the insulating paper 70 having the through-hole 71 protrudes outwardly from the housing 20 on the X2 side. Further, the external connection terminal 55 of the O-electrode plate 50 having the through-hole 54 protrudes outwardly from the housing 20 on the X1 side.

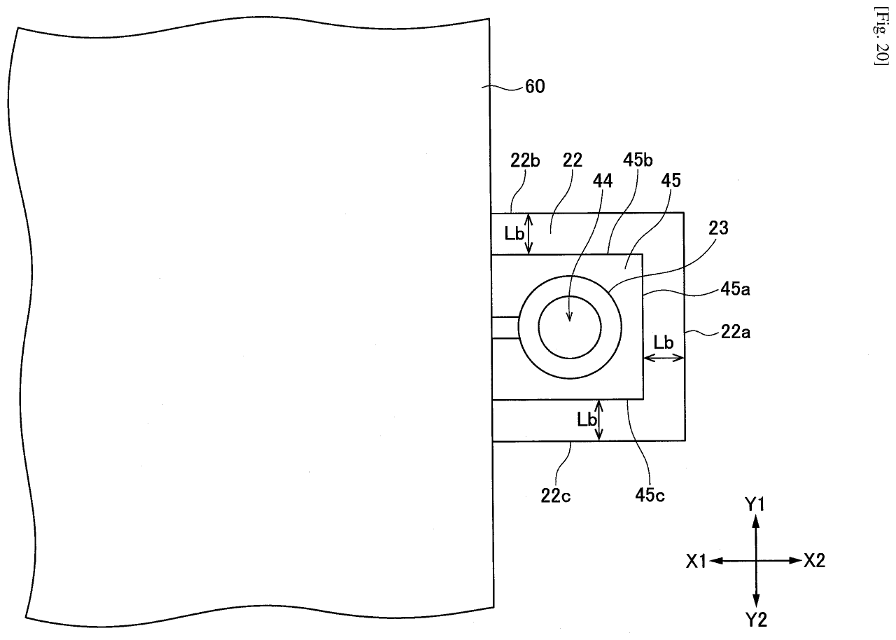

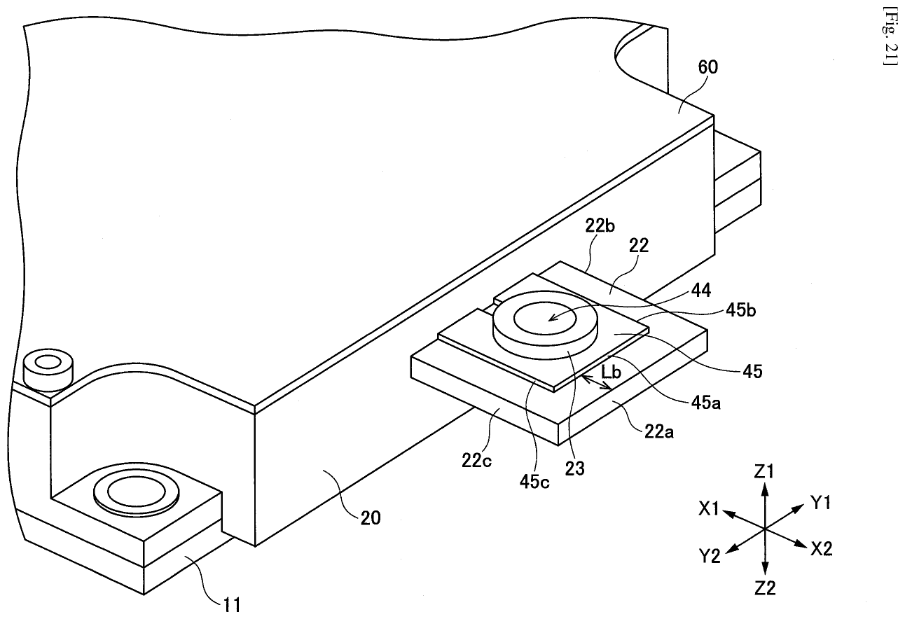

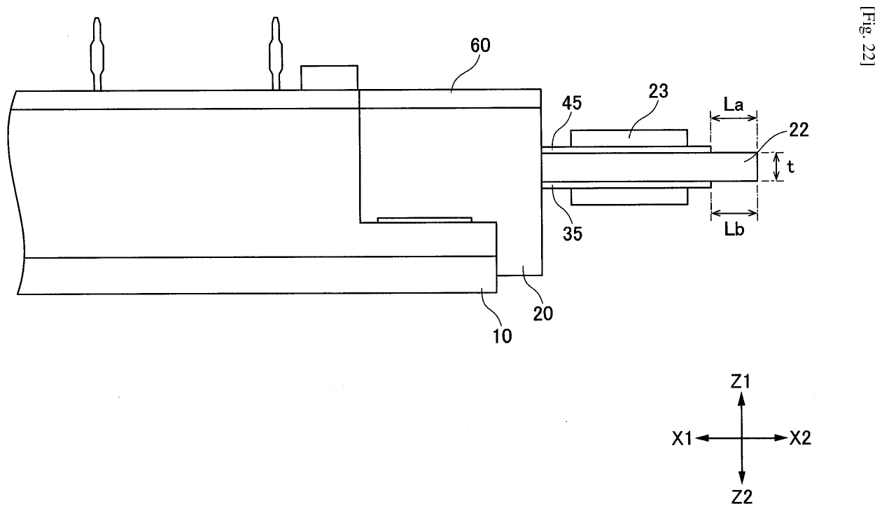

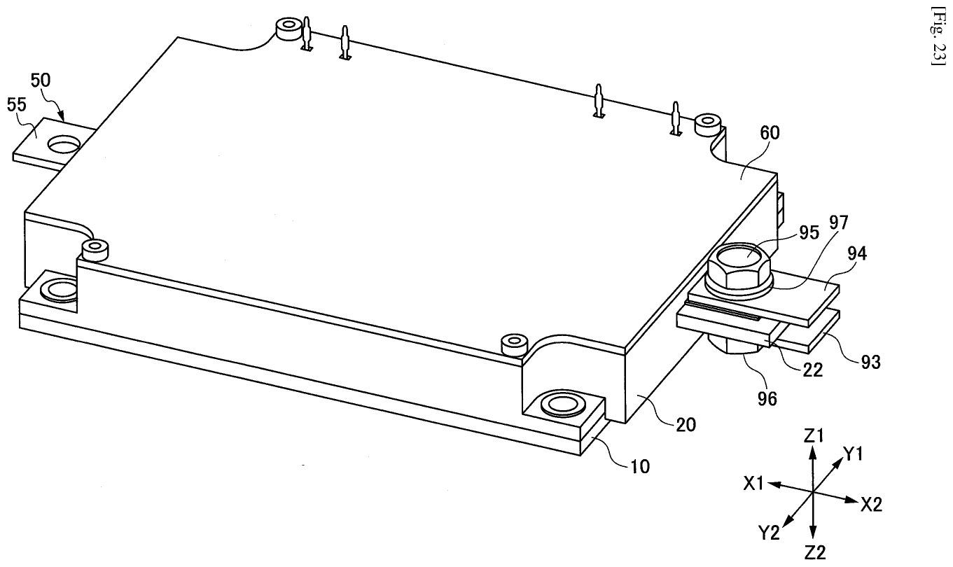

FIG. 18 is a plan view from the Z2 side of a main portion of the housing of FIG. 17. FIG.19 is a perspective view from the Z2 side, FIG. 20 is a plan view from the Z1 side, FIG. 21 is a perspective view from the Z1 side, and FIG. 22 is a side view of the main portion of the housing of FIG. 17.

As illustrated in FIG. 18 and FIG. 19, in a plan view from the Z2 side, the external connection terminal 35 of the P-electrode plate 30 is placed inward relative to the creepage insulating portion 22. A distance La from the edge 35a of the X2 side of the external connection terminal 35 to the edge 22a of the X2 side of the creepage insulating portion 22 is 4 mm. Further, a distance La from the edge 35b of the Y1 side of the external connection terminal 35 to the edge 22b of the Y1 side of the creepage insulating portion 22, and a distance La from the edge 35c of the Y2 side of the external connection terminal 35 to the edge 22c of the Y2 side of the creepage insulating portion 22 are also 4 mm.

Further, as illustrated in FIG. 20 and FIG. 21, in a plan view from the Z1 side, the external connection terminal 45 of the N-electrode plate 40 is placed inward relative to the creepage insulating portion 22. A distance Lb from the edge 45a of the X2 side of the external connection terminal 45 to the edge 22a of the X2 side of the creepage insulating portion 22 is 4 mm. Further, a distance Lb from the edge 45b of the Y1 side of the external connection terminal 45 to the edge 22b of the Y1 side of the creepage insulating portion 22, and a distance Lb from the edge 45c of the Y2 side of the external connection terminal 45 to the edge 22c of the Y2 side of the creepage insulating portion 22 are also 4 mm.

Further, as illustrated in FIG. 22, a thickness t of the creepage insulating portion 22 is 1.5 mm. Therefore, a creepage distance between the P-electrode plate 30 and the N-electrode plate 40, namely La+Lb+t is 9.5 mm.

In the present embodiment, the flat plate portion 31 of the P-electrode plate 30 and the flat plate portion 41 of the N-electrode plate 40 facing each other are insulated by the insulating paper 70. Further, the creepage distance between the external connection terminal 35 of the flat plate portion 31 of the P-electrode plate 30 (located on the outside of the housing 20) and the external connection terminal 45 of the flat plate portion 41 of the N-electrode plate 40 (located on the outside of the housing 20) is maintained at or above a predetermined value by the creepage insulating portion 22.

As illustrated in FIG. 4 or FIG. 26, which will be described below, in the semiconductor module according to the present embodiment, the insulating paper 70 is provided on the P-electrode plate 30, and the N-electrode plate 40 is provided on the insulating paper 70. Accordingly, the flat plate portion 31 of the P-electrode plate 30 and the flat plate portion 41 of the N-electrode plate 40 are securely insulated by the insulating paper 70 sandwiched therebetween. The distance between the flat plate portion 31 of the P-electrode plate 30 and the flat plate portion 41 of the N-electrode plate 40 is maintained at a predetermined distance such as 0.5 mm.

As illustrated in FIG. 18 and FIG. 20, in a plan view, the cylindrical portion 23 is inserted into the through-hole 34 of the P-electrode plate 30, the through-hole 44 of the N-electrode plate 40, and the through-hole 71 of the insulating paper 70, and the positions of the through-holes coincide with each other. Further, even outside the housing 20, insulation between the P-electrode plate 30 and the N-electrode plate 40 is secured by the creepage insulating portion 22 and the insulating paper 70 sandwiched between the external connection terminal 35 of the P-electrode plate 30 and the external connection terminal 45 of the N-electrode plate 40. Note that the term “coincide” is not intended to be construed in a strict sense, and is intended to be construed in a wider sense within the scope of the present invention.

As described above, by disposing the flat plate portion 31 of the P-electrode plate 30 and the flat plate portion 41 of the N-electrode plate 40 in parallel, it becomes possible to create large mutual inductance between the flat plate portion 31 of the P-electrode plate 30 and the flat plate portion 41 of the N-electrode plate 40. As a result, the P-N inductance (the inductance between the P-electrode plate and the N-electrode plate) of the semiconductor module can be decreased.

Specifically, the P-N inductance L of the semiconductor module is expressed by the following formula (1), where L1 denotes self-inductance of the P-electrode plate 30, L2 denotes self-inductance of the N-electrode plate 40, and M₁₂ denotes mutual inductance between the P-electrode plate 30 and the N-electrode plate 40.

L=L1+L2−2M₁₂ (1)

In the present embodiment, in order to increase the mutual inductance M₁₂, the flat plate portion 31 of the P-electrode plate 30 and the flat plate portion 41 of the N-electrode plate 40 are disposed in parallel, both inside and outside the housing 20. By increasing the area where the flat plate portion 31 of the P-electrode plate 30 and the flat plate portion 41 of the N-electrode plate 40 are disposed in parallel, the mutual inductance M₁₂ increases, thus allowing the P-N inductance L of the semiconductor module to be reduced.

Further, in the present embodiment, the vertical portion 32 of the P-electrode plate 30 and the vertical portion 42 of the N-electrode plate 40 are also disposed in parallel. As a result, the mutual inductance M₁₂ can be further increased, and the P-N inductance L of the semiconductor module can be decreased.

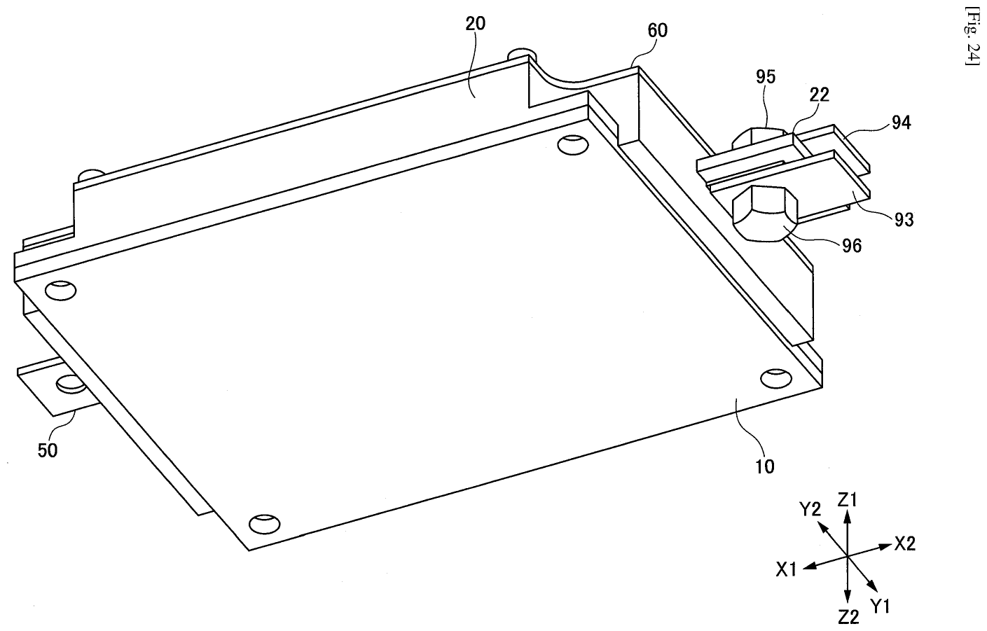

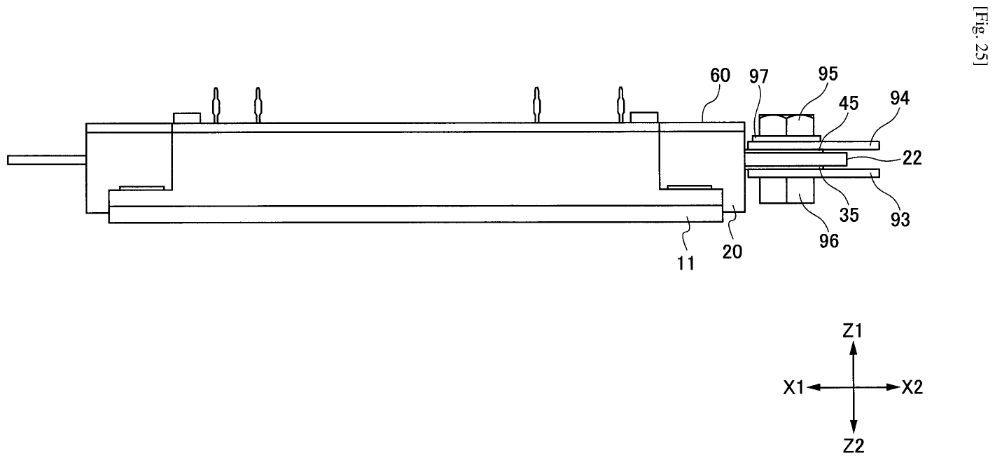

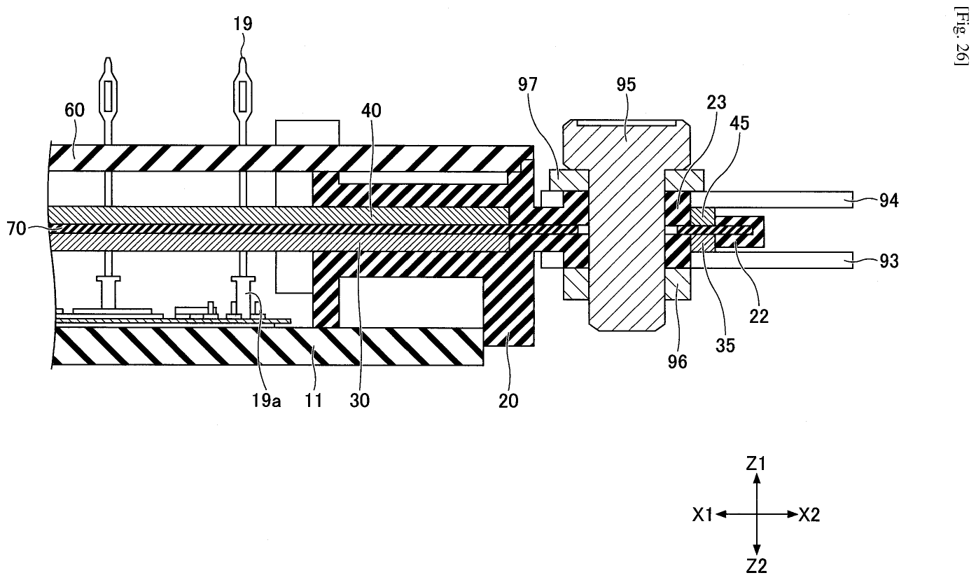

In the present embodiment, as illustrated in FIG. 23 through FIG. 26, a P-busbar 93 and an N-busbar 94 are fixed by a bolt 95 and a nut 96, with the external connection terminal 35 of the P-electrode plate 30 making contact with the P-busbar 93 and the external connection terminal 45 of the N-electrode plate 40 making contact with an N-busbar 94. Accordingly, the electrical connection between the external connection terminal 35 of the P-electrode plate 30 and the P-busbar 93 can be maintained, and the electrical connection between the external connection terminal 45 of the N-electrode plate 40 and the N-busbar 94 can be maintained. FIG. 23 is a perspective view from the Z1 side of the semiconductor module. FIG. 24 is a perspective view from the Z2 side of the semiconductor module. FIG. 25 is a side view of the semiconductor module. FIG. 26 is a cross-sectional view of a main part of the semiconductor module.

Specifically, the P-busbar 93 and the N-busbar 94 have through-holes passing therethrough in the Z1-Z2 direction. On the Z2 side of the insulating paper 70, the P-electrode plate 30 and the P-busbar 93 are stacked. The cylindrical portion 23 is inserted into the through-hole 34 of the P-electrode plate 30 and the through-hole of the P-busbar 93. On the Z1 side of the insulating paper 70, the N-electrode plate 40 and the N-busbar 94 are stacked. The cylindrical portion 23 is inserted into the through-hole 44 of the N-electrode plate 40 and the through-hole of the N-busbar 94.

In the above state, the bolt 95 is inserted, from the Z1 side, into the screw hole 23a of the cylindrical portion 23 via a spacer 97, and is fixed by the nut 96 at the Z2 side. Accordingly, the electrical connection between the external connection terminal 35 of the P-electrode plate 30 and the P-busbar 93 is maintained, and the electrical connection between the external connection terminal 45 of the N-electrode plate 40 and the N-busbar 94 is maintained. Note that the bolt 95, the nut 96, and the spacer 97 are formed of an insulating resin material.

As described above, in the semiconductor module according to the present embodiment, the external connection terminal 35 of the P-electrode plate 30 and the external connection terminal 45 of the N-electrode plate 40 are disposed in parallel outside the housing 20. Therefore, the P-electrode plate 30 and the N-electrode plate 40 are disposed in parallel, both inside and outside the housing 20. Accordingly, the mutual inductance M₁₂ can be increased, allowing the P-N inductance L of the semiconductor module to be reduced.

In a plan view from the Z1 side, the flat plate portion 31 of the P-electrode plate 30 and the flat plate portion 41 of the N-electrode plate 40 are arranged mostly alongside and parallel to each other.

Further, the present invention is not limited to these embodiments, but various variations and modifications may be made without departing from the scope of the present invention.

### REFERENCE SIGNS LIST

10 base member

11 base plate

11a surface

12 P-electrode pad

13 N-electrode pad

14 O-electrode pad

19 press-fit pin

20 housing

21 opening

22 creepage insulating portion

23 cylindrical portion

23a screw hole

27 connection hole

30 P-electrode plate

31 flat plate portion

32 vertical portion

33 connection portion

34 through-hole

35 external connection terminal

40 N-electrode plate

41 flat plate portion

42 vertical portion

43 connection portion

44 through-hole

45 external connection terminal

50 O-electrode plate

51 flat plate portion

52 vertical portion

53 connection portion

54 through-hole

55 external connection terminal

60 lid

61 through-hole

70 insulating paper

71 through-hole

93 P-busbar

94 N-busbar

95 bolt

96 nut

97 spacer

100 circuit board

101 first transistor

102 second transistor

1. A semiconductor module comprising:
a base member;
a circuit board provided on the base member and including a positive electrode pad, a negative electrode pad, and semiconductor devices, the semiconductor devices being electrically coupled to the positive electrode pad and the negative electrode pad;
a housing formed in a frame shape and attached to the base member so as to surround the positive electrode pad and the negative electrode pad;
a first electrode plate electrically coupled to the positive electrode pad and having a first flat plate portion;
a second electrode plate electrically coupled to the negative electrode pad and having a second flat plate portion; and
a first insulating member,
wherein the first flat plate portion of the first electrode plate and the second flat plate portion of the second electrode plate are disposed in parallel from inside of the housing to outside of the housing, and
wherein the first flat plate portion of the first electrode plate has a first external connection terminal situated outside the housing, and the second flat plate portion of the second electrode plate has a second external connection terminal situated outside the housing, the first insulating member being sandwiched between the first external connection terminal and the second external connection terminal.

2. The semiconductor module according to claim 1, wherein the first insulating member is insulating paper.

3. The semiconductor module according to claim 1, further comprising a second insulating member that is situated outside the housing so as to surround, in a plan view, the first external connection terminal of the first electrode plate and the second external connection terminal of the second electrode plate.

4. The semiconductor module according to claim 3, wherein the second insulating member is a part of the housing.

5. The semiconductor module according to claim 1, wherein the first external connection terminal of the first electrode plate has a first through-hole, the second external connection terminal of the second electrode plate has a second through-hole, and in a plan view, a position of the first through-hole of the first external connection terminal coincides with a position of the second through-hole of the second external connection terminal.

6. The semiconductor module according to claim 1, wherein the semiconductor devices are formed of a material including SiC.

7. A semiconductor module comprising:
a base member;
a circuit board provided on the base member and including a positive electrode pad, a negative electrode pad, and semiconductor devices, the semiconductor devices being electrically coupled to the positive electrode pad and the negative electrode pad;
a housing formed in a frame shape and attached to the base member so as to surround the positive electrode pad and the negative electrode pad;
a first electrode plate electrically coupled to the positive electrode pad and having a first flat plate portion;
a second electrode plate electrically coupled to the negative electrode pad and having a second flat plate portion, and
a first insulating member; and
a second insulating member,
wherein the first flat plate portion of the first electrode plate and the second flat plate portion of the second electrode plate are disposed in parallel from inside of the housing to outside of the housing,
wherein the first flat plate portion of the first electrode plate has a first external connection terminal situated outside the housing, and the second flat plate portion of the second electrode plate has a second external connection terminal situated outside the housing, the first insulating member being sandwiched between the first external connection terminal and the second external connection terminal,
wherein the first insulating member is insulating paper,
wherein the second insulating member is situated outside the housing so as to surround, in a plan view, the first external connection terminal of the first electrode plate and the second external connection terminal of the second electrode plate,
wherein the second insulating member is a part of the housing,
wherein the first external connection terminal of the first electrode plate has a first through-hole, the second external connection terminal of the second electrode plate has a second through-hole, and in a plan view, a position of the first through-hole of the first external connection terminal coincides with a position of the second through-hole of the second external connection terminal, and
wherein the semiconductor devices are formed of a material including SiC.
